(19) United States
(12) Patent Application Publication
(10) Pub. No.: US 2010/0117164 A1
(43) Pub. Date: May 13, 2010

(54) SEMICONDUCTOR DEVICE WITH A LOW JFET REGION RESISTANCE

(76) Inventors: Wei-Chieh Lin, Hsinchu City (TW); Ho-Tai Chen, Taipei County (TW); Hsin-Yu Hsu, Chiayi County (TW)

Correspondence Address: NORTH AMERICA INTELLECTUAL PROPERTY CORPORATION, P.O. BOX 506, MERRIFIELD, VA, 22116, US

(21) Appl. No.: 12/426,950

(22) Filed: Apr. 20, 2009

(30) Foreign Application Priority Data
Nov. 13, 2008 (TW) 097143849

(51) Int. Cl. H01L 29/78

(52) U.S. Cl. 257/412; 257/E29.255

(57) ABSTRACT

A high-voltage MOS transistor device includes a substrate, a semiconductor layer formed on the substrate, a gate structure having an opening, formed on the semiconductor layer, a first source/drain region of a first conductivity type formed in the semiconductor layer at one side of the gate structure, a second source/drain region of the first conductivity type formed in the semiconductor layer at the other side of the gate structure, a channel region disposed by a dopant of the first conductivity type between the first source/drain region and the second source/drain region, and a doping region of the first conductivity type formed in the channel region and under the opening of the gate structure, wherein a doping concentration of the doping region is higher than a doping concentration of the channel region.

### BACKGROUND OF THE INVENTION

1. Field of the Invention

The present invention relates to a high-voltage metal-oxide-semiconductor transistor device, and more particularly, to a high-voltage metal-oxide-semiconductor transistor device having low drain-source on-state resistance and low gate-drain capacitance.

2. Description of the Prior Art

High-voltage metal-oxide semiconductor (MOS) transistor devices are used as switches and are broadly utilized in power suppliers, power management systems and consumer electronics products. The switching speed of a high-voltage MOS transistor device is influenced by a drain-source on-state resistance R_{dson} and a gate-drain capacitance C_{gd}, also called Miller capacitance. For this reason, designers make efforts to design a MOS transistor device with low R_{dson} and low C_{gd}, capable of withstanding high-voltages.

Please refer to FIG. 1, which is a cross-section diagram of an n-type MOS transistor device 100 according to the prior art. The n-type MOS transistor device 100 is a high-voltage MOS transistor and comprises an n-type substrate 10, an n-type semiconductor layer 12, a gate structure 14, a p-type well region 16 and an n-type source/drain region 18. The gate structure 14 includes a lower gate oxide layer and an upper gate polysilicon layer, which are well-known and are not numbered. The p-type well region 16 is formed in the n-type semiconductor layer 12 respectively at two sides of the gate structure 14. The n-type source/drain region 18 is formed in the p-type well region 16. As the well-known in the prior art, R_{dson} of the MOS transistor device is a summation of resistances of a source diffusion region, a channel region, an accumulation layer, a junction field effect transistor (JFET) region and a substrate. As shown in FIG. 1, the channel length of the channel region of the n-type MOS transistor device 100 is large enough, which result in a low R_{dson}.

Note that, the gate structure 14 having a large gate length generates a large C_{gd}. In order to decrease C_{gd}, a conventional technique reduces the gate length. If the channel length is fixed, the reduced gate length results in a reduced accumulation layer and a reduced JFET region such that the R_{dson} rises accordingly. Another technique to decrease C_{gd}, disclosed in the U.S. Pat. No. 6,534,825, is a MOS transistor device having a dopant in an accumulation layer under a gate structure, which has a conductivity type identical to the conductivity type of a substrate and a doping concentration lighter than the substrate has. However, the problem of a rising R_{dson} is still not solved.

With the development of semiconductor technology, demands for high-voltage MOS transistor devices with high switching speed are increasing. Therefore, it is necessary to produce a high-voltage MOS transistor device with low R_{dson} and low C_{gd}.

### SUMMARY OF THE INVENTION

It is therefore a primary objective of the claimed invention to provide a high-voltage MOS transistor device with low R_{dson} and low C_{gd}.

The present invention discloses a high-voltage MOS transistor device includes a substrate, a semiconductor layer formed on the substrate, a gate structure having an opening, formed on the semiconductor layer, a first source/drain region of a first conductivity type formed in the semiconductor layer at one side of the gate structure, a second source/drain region of the first conductivity type formed in the semiconductor layer at the other side of the gate structure, a channel region disposed by a dopant of the first conductivity type between the first source/drain region and the second source/drain region, and a doping region of the first conductivity type formed in the channel region, under the opening of the gate structure, wherein a doping concentration of the doping region is higher than a doping concentration of the channel region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-section diagram of an n-type MOS transistor device according to the prior art.

FIG. 2 is a cross-section diagram of an n-type MOS transistor device shown in according to an embodiment of the present invention.

FIG. 3 to FIG. 5 are perspective diagrams of the n-type MOS transistor device shown in FIG. 2.

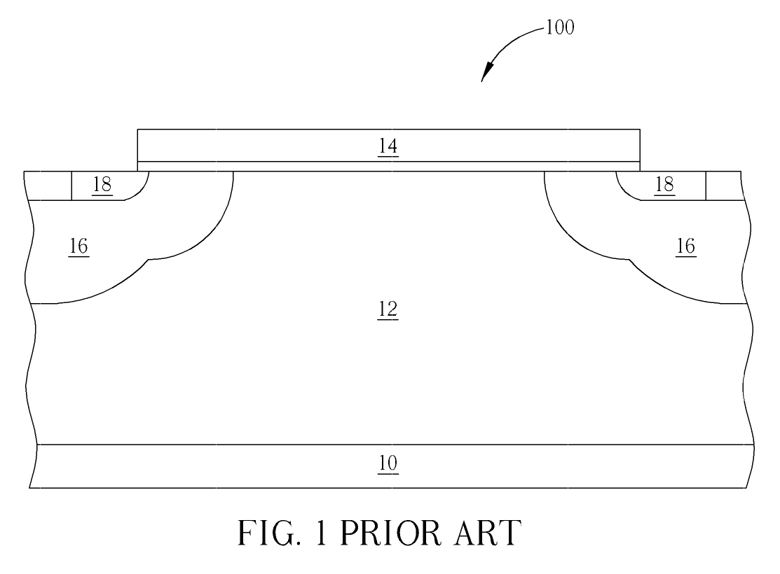

### DETAILED DESCRIPTION

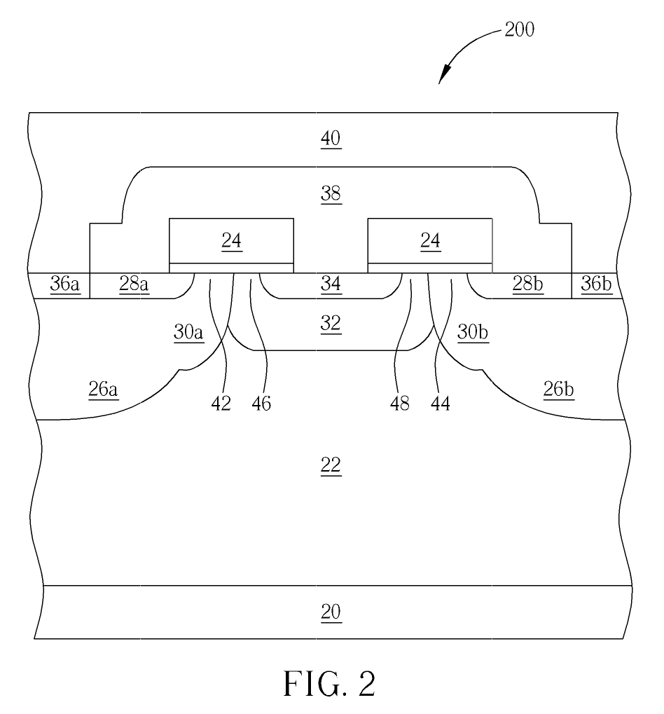

Please refer to FIG. 2, which is a cross-section diagram of an n-type MOS transistor device 200 according to an embodiment of the present invention. The n-type MOS transistor device 200 is a high-voltage MOS transistor and comprises an n-type substrate 20, an n-type semiconductor layer 22, a gate structure 24, p-type well regions 26a and 26b, p-type bases 28a and 28b, n-type source/drain regions 30a and 30b, a channel region 32, an n-type doping region 34, p-type doping regions 36a and 36b, an interlevel dielectric (ILD) layer 38, and a metal layer 40.

The n-type substrate 20 can be a silicon substrate. The n-type semiconductor layer 22 can be an epitaxial layer which is formed on the n-type substrate 20 by a chemical vapor deposition process. The p-type well regions 26a and 26b are formed in the n-type semiconductor layer 22 by an ion implantation process. After the p-type well regions 26a and 26b are formed, an n-type dopant is doped into a region between the p-type well region 26a and the p-type well region 26b before the gate structure 24 is formed. The gate structure 24 is a spilt gate structure including a lower gate oxide layer and an upper gate polysilicon layer, and is formed on the n-type semiconductor layer 22. The composition of the gate structure 24 is well-known to those skilled in the art, and the gate oxide layer and the gate polysilicon layer are not numbered in the following figures. The gate structure 24 has an opening dividing the gate structure 24 into two parts, which makes part of the n-type semiconductor layer 22 under the opening exposed. The gate structure 24 is a stack of an oxide layer and a polysilicon layer formed on the oxide layer, which is well-known in the prior art and is not given here. The p-type bases 28a and 28b are formed in the p-type well region 26a and 26b respectively by another ion implantation process, near the channel region 32. After the p-type bases 28a and 28b are formed, the n-type source/drain region 30a and 30b are formed in the p-type well regions 26a and 26b respectively at two side of the gate structure 24.

The region between the n-type source/drain regions 30a and 30b is the channel region 32, which comprises the n-type dopant doped after the p-type well regions 26a and 26b are formed. The n-type doping region 34 is formed in the channel region 32 and under the opening of the gate structure 24. Note that the doping concentration of the n-type doping region 34 is higher that the doping concentration of the n-type dopant in the channel region 32. The p-type doping regions 36a and 36b are formed at the outside of the n-type source/drain region 30a and 30b. The ILD layer 38 is formed over the gate structure 24, the opening, and the n-type source/drain regions 30a and 30b. The metal layer 40 is formed over the ILD layer 38 and the p-type doping regions 36a and 36b.

Note that the gate structure 24 is a split gate structure, in which the gate length is shorter than a conventional gate structure, so that the n-type MOS transistor device 200 has a smaller C_{gd}. Besides, a doping process of the n-type dopant in the channel region 32 makes the channel length short so as to keep an R_{dson} the same. Therefore, a JFET region in the channel region 32 is kept large enough to prevent the R_{dson} from increasing. In other words, the embodiment of the present invention improves the R_{dson} by decreasing the resistance of the JFET region. Compared with the prior art, the embodiment of the present invention improves both the C_{gd} and the R_{dson}.

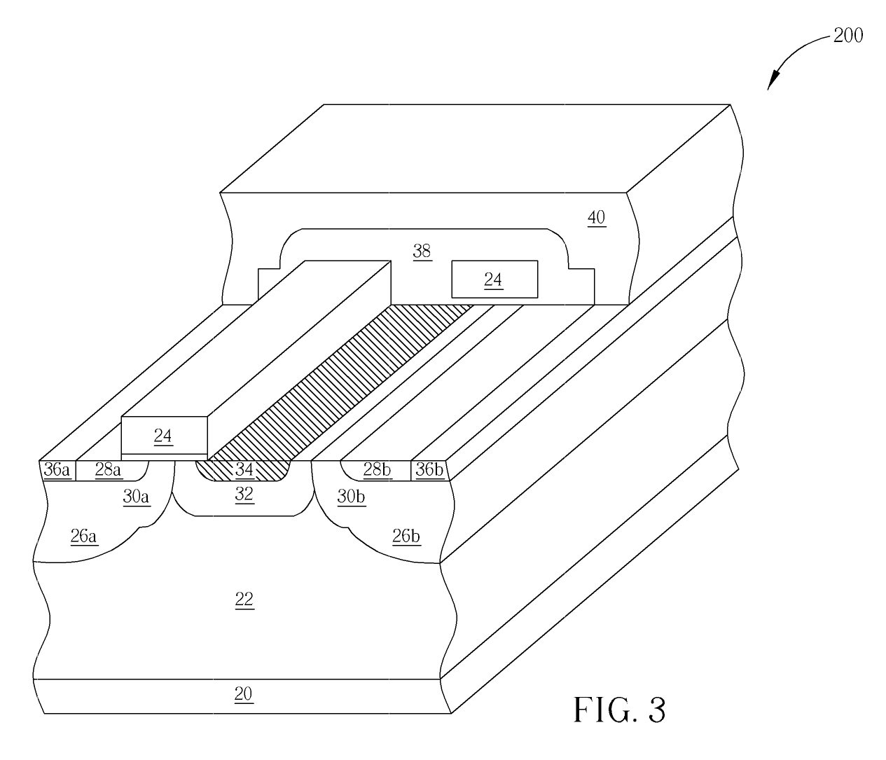

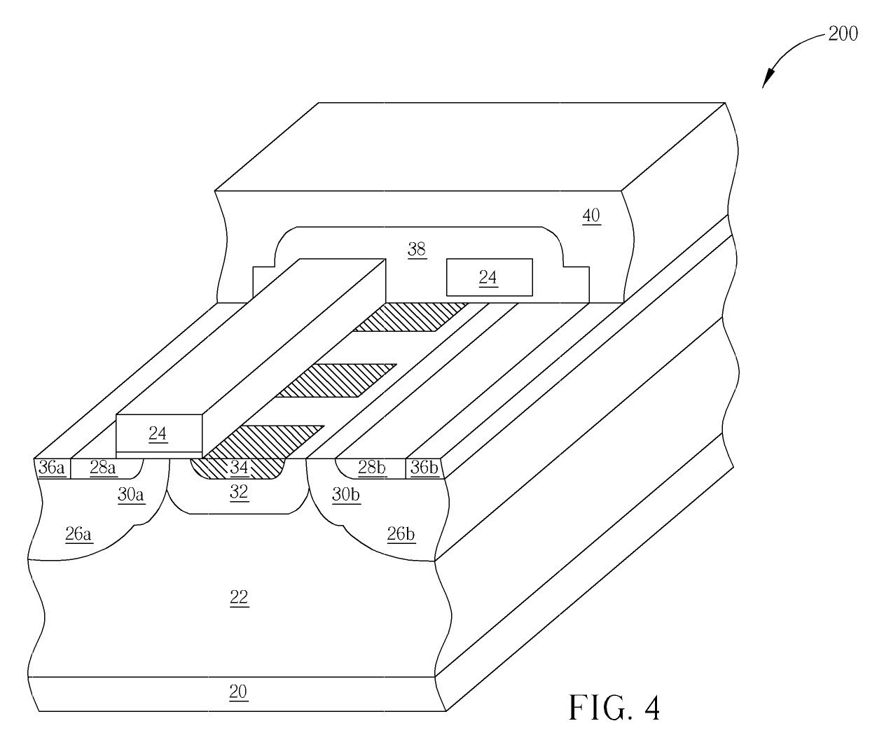

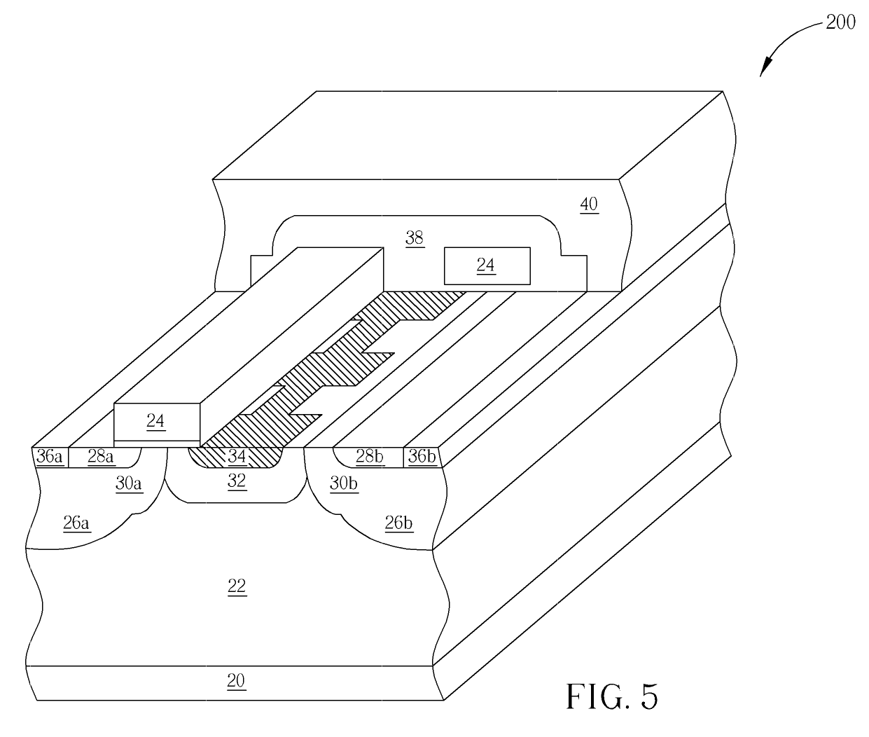

In the n-type MOS transistor device 200, the n-type doping region 34 is formed in the channel region 32 and the doping concentration of the n-type doping region 34 is higher than the doping concentration of the n-type dopant in the channel region 32. Please refer to FIG. 2 and pay attention to the regions 46 and 48 between the n-type doping region 34 and the n-type source/drain regions 30a and 30b, which act as channels to provide additional current paths. The n-type doping region 34 and the n-type source/drain region 30a and 30b are formed through the same mask process. The n-type doping region 34 is formed through a patterned photo-resist layer. Please refer to FIG. 3, FIG. 4 and FIG. 5, which are perspective diagrams of the n-type MOS transistor device 200. In order to enhance the capability of withstanding high-voltages, the n-type doping region 34 are in different patterns (which are shown as the slash area in FIG. 3, FIG. 4 and FIG. 5) through different patterned photo-resist layers. Note that the n-type MOS transistor device 200 is one embodiment of the present invention, and the present invention can also be applied in the p-type MOS transistor device.

In conclusion, the present invention uses the split gate structure to decrease the C_{gd} and has the dopant of a light concentration in the channel region to decrease the channel length, such that the R_{dson} remains. Furthermore, the patterned doping region in the channel region provides additional current paths and enhances the capability of withstanding high-voltages.

Those skilled in the art will readily observe that numerous modifications and alterations of the device and method may be made while retaining the teachings of the invention.

What is claimed is:

1. A high-voltage metal-oxide-semiconductor (MOS) transistor device comprising:
a substrate;
a semiconductor layer formed on the substrate;
a gate structure having an opening, formed on the semiconductor layer;
a first source/drain region of a first conductivity type formed in the semiconductor layer at one side of the gate structure;
a second source/drain region of the first conductivity type formed in the semiconductor layer at the other side of the gate structure;
a channel region disposed by a dopant of the first conductivity type between the first source/drain region and the second source/drain region; and
a doping region of the first conductivity type formed in the channel region, under the opening of the gate structure, wherein a doping concentration of the doping region is higher than a doping concentration of the channel region.

2. The high-voltage MOS transistor device of claim 1 further comprising a first well region of a second conductivity type and a second well region of the second conductivity type formed in the semiconductor layer, in which the first source/drain region and the second source/drain region are respectively formed.

3. The high-voltage MOS transistor device of claim 2 further comprising a first base of the second conductivity type and a second base of the second conductivity type, respectively formed in the first well region and the second well region.

4. The high-voltage MOS transistor device of claim 2, wherein the first conductivity type is n-type and the second conductivity type is p-type.

5. The high-voltage MOS transistor device of claim 2, wherein the first conductivity type is p-type and the second conductivity type is n-type.

6. The high-voltage MOS transistor device of claim 1, wherein the doping region, the first source/drain region and the second source/drain region are formed in the same process.

7. The high-voltage MOS transistor device of claim 1, wherein the doping region is formed through a patterned photo-resist layer.

8. The high-voltage MOS transistor device of claim 1, wherein the gate structure comprises an oxide layer and a polysilicon layer formed on the oxide layer.

9. The high-voltage MOS transistor device of claim 1 further comprising an interlevel dielectric layer formed on the gate structure.

10. The high-voltage MOS transistor device of claim 9 further comprising a metal layer formed on the interlevel dielectric layer.
